(19) United States
(12) Patent Application Publication
(10) Pub. No.: US 2012/0007588 A1
(43) Pub. Date: Jan. 12, 2012

(54) CLAMP METER FOR MEASURING VOLTAGE AND CURRENT SIMULTANEOUSLY AND METHOD FOR THE SAME

(75) Inventor: Po-Chao TAN, Chung-Ho City (TW)

(73) Assignee: Brymen Technology Corporation.

(21) Appl. No.: 12/830,596

(22) Filed: Jul. 6, 2010

(51) Int. Cl. G01R 1/20

(52) U.S. Cl. 324/126

(57) ABSTRACT

A clamp meter for measuring voltage and current simultaneously includes a microcontroller unit, a current-side analog-digital converter unit electrically connected to the microcontroller unit and a current-measuring unit, a voltage-side analog-digital converter unit electrically connected to the microcontroller unit and a voltage-measuring unit. By providing dedicated analog-digital converter unit to the current-measuring unit and the voltage-measuring unit, the clamp meter is capable of measuring voltage and current precisely and simultaneously.

### BACKGROUND OF THE INVENTION

1. Field of the Invention

The present invention relates to a clamp meter for measuring voltage and current and method for the same, and in particular to a clamp meter for measuring voltage and current simultaneously and method for the same.

2. Description of Prior Art

A clamp meters is a common electronic measurement apparatus similar to a multimeter.

There is a shortcoming in the prior art clamp meter, that is the prior art clamp meter is not capable of measuring the current and the voltage of a measured object (namely, a device under measurement) simultaneously. The reason caused is that there is only one analog-digital converter switching between the current measuring side and the voltage measuring side. The analog-digital converter may be switched to voltage measuring side to measure the voltage value of the measured object, and then switched to current measuring side to measure the current value of the measured object.

Thus, although the prior art clamp meter may display the voltage value and the current value of the measured object when using the prior art clamp meter to measure the voltage value and the current value of the measured object in the same time, in fact the measuring timing of the voltage value and the current value are different. Therefore, it is not really a simultaneously measuring. Precisely and simultaneously measuring the voltage value and the current value of the measured object is very important. For example, the voltage is dropping while the current is rising at the moment a machine is started. The instant phenomenon is not precise enough if the voltage value and the current value are not measured simultaneously.

### SUMMARY OF THE INVENTION

In order to solve the above-mentioned problems, an object of the present invention is to provide a clamp meter for measuring voltage and current simultaneously, thus precisely and simultaneously measuring the voltage and the current of a measured object.

In order to solve the above-mentioned problems, another object of the present invention is to provide a method for using a clamp meter to measure voltage and current simultaneously, thus precisely and simultaneously measuring the voltage and the current of a measured object.

In order to achieve the object of the present invention mentioned above, the clamp meter for measuring voltage and current simultaneously of present invention includes a microcontroller unit, a current-side analog-digital converter unit electrically connected to the microcontroller unit, a current-measuring unit electrically connected to the current-side analog-digital converter unit, a voltage-side analog-digital converter unit electrically connected to the microcontroller unit, and a voltage-measuring unit electrically connected to the voltage-side analog-digital converter unit.

In order to achieve another object of the present invention mentioned above, the method for using a clamp meter to measure voltage and current simultaneously of present invention is applied to a clamp meter to measure a measured object. The method includes the steps: providing a current-side analog-digital converter unit in the clamp meter; the current-side analog-digital converter unit is electrically connected to a microcontroller unit and a current-measuring unit of the clamp meter; providing a voltage-side analog-digital converter unit in the clamp meter; the voltage-side analog-digital converter unit is electrically connected to the microcontroller unit and a voltage-measuring unit of the clamp meter; measuring the current and the voltage of the measured object simultaneously by the current-measuring unit and the voltage-measuring unit respectively to get a current-measuring signal and a voltage-measuring signal; sending the current-measuring signal and the voltage-measuring signal from the current-measuring unit and the voltage-measuring unit to the current-side analog-digital converter unit and the voltage-side analog-digital converter unit respectively to get a digital current signal and a digital voltage signal simultaneously; sending the digital current signal and the digital voltage signal simultaneously from the current-side analog-digital converter unit and the voltage-side analog-digital converter unit respectively to the microcontroller unit.

### BRIEF DESCRIPTION OF DRAWING

FIG. 1 shows a block diagram of a clamp meter for measuring voltage and current simultaneously of the present invention.

FIG. 2 shows a flowchart of a method for using a clamp meter to measure voltage and current simultaneously of the present invention.

### DETAILED DESCRIPTION OF THE INVENTION

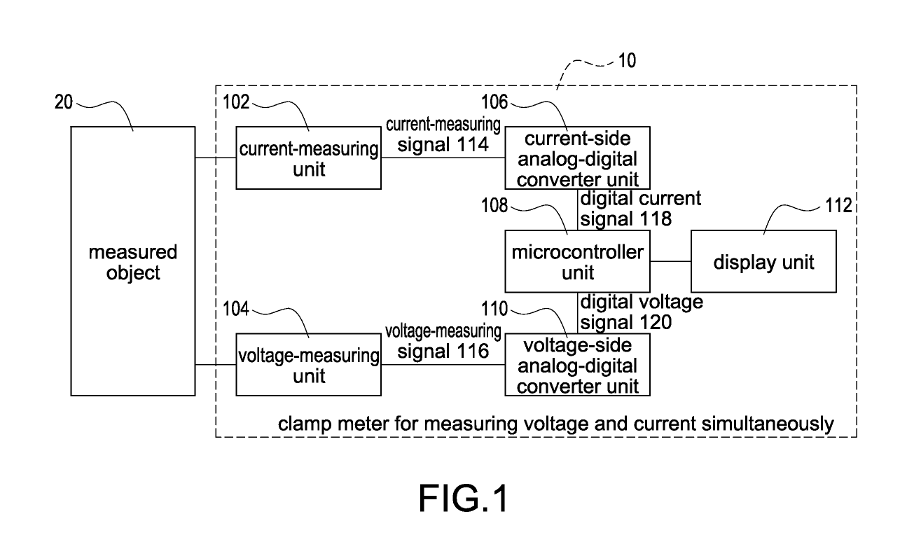

FIG. 1 shows a block diagram of a clamp meter for measuring voltage and current simultaneously of the present invention. The clamp meter 10 for measuring voltage and current simultaneously according to the present invention is applied to a measured object 20. The clamp meter 10 includes a current-measuring unit 102, a voltage-measuring unit 104, a current-side analog-digital converter unit 106 (for example, a fast high resolution analog-digital converter), a microcontroller unit 108, a voltage-side analog-digital converter unit 110 (for example, a fast high resolution analog-digital converter), and a display unit 112.

The current-measuring unit 102 is electrically connected to the measured object 20 and the current-side analog-digital converter unit 106. The voltage-measuring unit 104 is electrically connected to the measured object 20 and the voltage-side analog-digital converter unit 110. The microcontroller unit 108 is electrically connected to the current-side analog-digital converter unit 106, the voltage-side analog-digital converter unit 110, and the display unit 112.

The current and the voltage of the measured object 20 are measured simultaneously by the current-measuring unit 102 and the voltage-measuring unit 104 respectively to get a current-measuring signal 114 and a voltage-measuring signal 116. The current-measuring signal 114 and the voltage-measuring signal 116 are sent from the current-measuring unit 102 and the voltage-measuring unit 116 to the current-side analog-digital converter unit 106 and the voltage-side analog-digital converter unit 110 respectively to get a digital current signal 118 and a digital voltage signal 120 simultaneously. The digital current signal 118 and the digital voltage signal 120 are sent simultaneously from the current-side analog-digital converter unit 106 and the voltage-side analog-digital converter unit 110 respectively to the microcontroller unit 108. The values of the digital current signal 118 and the digital voltage signal 120 are displayed on the display unit 112.

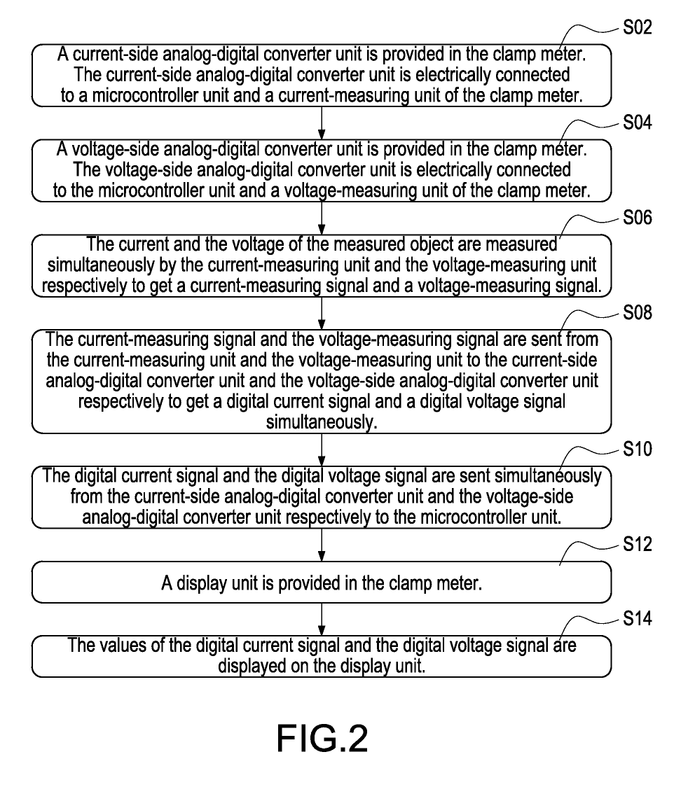

FIG. 2 shows a flowchart of a method for using a clamp meter to measure voltage and current simultaneously of the present invention. The method for using a clamp meter to measure voltage and current simultaneously according to the present invention is applied to a clamp meter to measure a measured object. The method includes the steps as follows. Firstly, a current-side analog-digital converter unit is provided in the clamp meter. The current-side analog-digital converter unit is electrically connected to a microcontroller unit and a current-measuring unit of the clamp meter (S02). A voltage-side analog-digital converter unit is provided in the clamp meter. The voltage-side analog-digital converter unit is electrically connected to the microcontroller unit and a voltage-measuring unit of the clamp meter (S04).

Afterward, the current and the voltage of the measured object are measured simultaneously by the current-measuring unit and the voltage-measuring unit respectively to get a current-measuring signal and a voltage-measuring signal (S06). The current-measuring signal and the voltage-measuring signal are sent from the current-measuring unit and the voltage-measuring unit to the current-side analog-digital converter unit and the voltage-side analog-digital converter unit respectively to get a digital current signal and a digital voltage signal simultaneously (S08). The digital current signal and the digital voltage signal are sent simultaneously from the current-side analog-digital converter unit and the voltage-side analog-digital converter unit respectively to the microcontroller unit (S10).

Finally, a display unit is provided in the clamp meter (S12). The values of the digital current signal and the digital voltage signal are displayed on the display unit (S14).

The current and the voltage of the measured object can be measured simultaneously by providing two analog-digital converters in the current measuring side and the voltage measuring side respectively of the clamp meter of the present invention. The present invention is unlike prior art, there is time difference between measuring current and voltage of the measured object in prior art clamp meter because there is only one analog-digital converter. Besides, please refer to FIG. 1 again. According to one embodiment of the present invention, the current-side analog-digital converter unit 106, the microcontroller unit 108, and the voltage-side analog-digital converter unit 110 are integrated in a chip and the data buses are simultaneous.

Although the present invention has been described with reference to the preferred embodiment thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A clamp meter for measuring voltage and current simultaneously includes:
a microcontroller unit;
a current-side analog-digital converter unit electrically connected to the microcontroller unit;
a current-measuring unit electrically connected to the current-side analog-digital converter unit;
a voltage-side analog-digital converter unit electrically connected to the microcontroller unit; and
a voltage-measuring unit electrically connected to the voltage-side analog-digital converter unit.

2. The clamp meter for measuring voltage and current simultaneously in claim 1, further includes a display unit electrically connected to the microcontroller unit.

3. The clamp meter for measuring voltage and current simultaneously in claim 1, wherein the current-side analog-digital converter unit is a fast high resolution analog-digital converter.

4. The clamp meter for measuring voltage and current simultaneously in claim 1, wherein the voltage-side analog-digital converter unit is a fast high resolution analog-digital converter.

5. A method for using a clamp meter to measure voltage and current simultaneously and applied to a clamp meter to measure a measured object; the method including the steps:
a. providing a current-side analog-digital converter unit in the clamp meter; wherein the current-side analog-digital converter unit is electrically connected to a microcontroller unit and a current-measuring unit of the clamp meter;
b. providing a voltage-side analog-digital converter unit in the clamp meter; wherein the voltage-side analog-digital converter unit is electrically connected to the microcontroller unit and a voltage-measuring unit of the clamp meter;
c. measuring the current and the voltage of the measured object simultaneously by the current-measuring unit and the voltage-measuring unit respectively to get a current-measuring signal and a voltage-measuring signal;
d. sending the current-measuring signal and the voltage-measuring signal from the current-measuring unit and the voltage-measuring unit to the current-side analog-digital converter unit and the voltage-side analog-digital converter unit respectively to get a digital current signal and a digital voltage signal simultaneously; and
e. sending the digital current signal and the digital voltage signal simultaneously from the current-side analog-digital converter unit and the voltage-side analog-digital converter unit respectively to the microcontroller unit.

6. The method for using a clamp meter to measure voltage and current simultaneously in claim 5 further including the step:
f. providing a display unit in the clamp meter.

7. The method for using a clamp meter to measure voltage and current simultaneously in claim 6 further including the step:
g. displaying the values of the digital current signal and the digital voltage signal on the display unit.

8. The method for using a clamp meter to measure voltage and current simultaneously in claim 5, wherein the current-side analog-digital converter unit is a fast high resolution analog-digital converter.

9. The method for using a clamp meter to measure voltage and current simultaneously in claim 5, wherein the voltage-side analog-digital converter unit is a fast high resolution analog-digital converter.
